(19) United States
(12) Patent Application Publication
(10) Pub. No.: US 2026/0362950 A1
(43) Pub. Date: Nov. 12, 2026

(54) DISPLAY APPARATUS, DISPLAY PANEL AND MANUFACTURING METHOD THEREOF

(71) Applicants: Beijing BOE Technology Development Co., Ltd., Beijing (CN); BOE Technology Group Co., Ltd., Beijing (CN)

(72) Inventors: Tianhao LU, Beijing (CN); Xiaohu LI, Beijing (CN); Lu WANG, Beijing (CN); Qian JIN, Beijing (CN); Xu LIU, Beijing (CN); Hongli WANG, Beijing (CN); Tong WU, Beijing (CN)

(73) Assignees: Beijing BOE Technology Development Co., Ltd., Beijing (CN); BOE Technology Group Co., Ltd., Beijing (CN)

(21) Appl. No.: 19/117,101

(22) PCT Filed: Dec. 15, 2023
(86) PCT No.: PCT/CN2023/139076

§ 371 Date: Mar. 31, 2025

(51) Int. Cl. H10K 59/80; H10K 59/12

(52) U.S. Cl. CPC H10K 59/879; H10K 59/1201

(57) ABSTRACT

A display apparatus, a display panel and a manufacturing method thereof. The light-emitting device of the display panel is provided on one side of the driving backplane; the light-emitting devices include first light-emitting devices, second light-emitting devices and third light-emitting devices emitting different colors; each of the light-emitting devices is divided into a plurality of light-emitting units distributed in an array along a first direction and a second direction; one of the light-emitting units includes the first light-emitting device and at least one of the second light-emitting device and the third light-emitting device; an area of an orthographic projection of the first light-emitting device on the driving backplane is greater than 4 times an area of an orthographic projection of any one of the second light-emitting device and the third light-emitting device on the driving backplane.

### CROSS-REFERENCE TO RELATED APPLICATION

The present application is a National Stage of International Application No. PCT/CN2023/139076, filed on Dec. 15, 2023, the entire disclosure of which is incorporated herein by reference for all purposes.

### TECHNICAL FIELD

The present disclosure relates to the field of display technology, and more specifically, to a display apparatus, a display panel and a manufacturing method of a display panel.

### BACKGROUND

Organic electroluminescent display panels have been widely used, and they use organic light-emitting diodes as light-emitting devices. However, the light extraction efficiency of the display panel is limited, resulting in low brightness. If the brightness is to be increased, the power consumption needs to be increased.

It should be noted that the information disclosed in the above Background section is only used to enhance the understanding of the background of the present disclosure, and therefore may include information that does not constitute prior art known to ordinary technicians in the field.

### SUMMARY

The present disclosure provides a display apparatus, a display panel and a manufacturing method of a display panel.

According to one aspect of the present disclosure, a display panel is provided, including:
a driving backplane;
a plurality of light-emitting devices, provided on a side of the driving backplane; wherein the light-emitting devices include first light-emitting devices, second light-emitting devices and third light-emitting devices emitting different colors; each of the light-emitting devices is divided into a plurality of light-emitting units distributed in an array along a first direction and a second direction; one of the light-emitting units includes the first light-emitting device and at least one of the second light-emitting device and the third light-emitting device; an area of an orthographic projection of the first light-emitting device on the driving backplane is greater than 4 times an area of an orthographic projection of any one of the second light-emitting device and the third light-emitting device on the driving backplane; and
a plurality of lenses, arranged in an array on a side of the light-emitting devices away from the driving backplane; the lenses include first lenses overlapping with the first light-emitting devices; the lenses contract in a direction away from the driving backplane and are configured to converge light emitted by the light-emitting devices overlapping with the lenses.

In an example implementation of the present disclosure, a spacing between two adjacent light-emitting devices is not less than 22 μm; a boundary of the orthographic projection of the first light-emitting device on the driving backplane is a polygon, and a side length of at least one side of the polygon is greater than 18 μm; a maximum distance between two points in a boundary of an orthographic projection of the identical first lens on the driving backplane is not less than 25 μm; and a spacing between two adjacent first lenses is not less than 10 μm.

In an example implementation of the present disclosure, the lenses further include second lenses overlapping with the second light-emitting devices and third lenses overlapping with the third light-emitting devices; the orthographic projection of the first lens on the driving backplane is greater than orthographic projections of the second lens and the third lens on the driving backplane;
the spacing between two adjacent first lenses is less than a spacing between the first lens and any one of the second lens and the third lens.

In an example implementation of the present disclosure, a number of light-emitting devices of one light-emitting unit is two; the light-emitting units include first light-emitting units and second light-emitting units alternately distributed in the first direction and the second direction;
light-emitting devices of the first light-emitting unit are the first light-emitting device and the second light-emitting device, and light-emitting devices of the second light-emitting unit are the first light-emitting device and the third light-emitting device.

In an example implementation of the present disclosure, a number of light-emitting devices of one light-emitting unit is three, including the first light-emitting device, the second light-emitting device and the third light-emitting device.

In an example implementation of the present disclosure, a spacing distance between two adjacent light-emitting units is not less than 99.2 μm and less than 145.6 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and
a maximum distance between two points in a boundary of an orthographic projection of the identical third lens on the driving backplane is not greater than 25 μm.

In an example implementation of the present disclosure, a spacing distance between two adjacent light-emitting units is not less than 145.6 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm.

In an example implementation of the present disclosure, a spacing distance between two adjacent light-emitting units is not less than 145.6 μm and less than 187 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and
a maximum distance between two points in a boundary of an orthographic projection of the identical third lens on the driving backplane is not greater than 25 μm.

In an example implementation of the present disclosure, a spacing distance between two adjacent light-emitting units is not less than 187 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm.

In an example implementation of the present disclosure, the lens is a spherical cap structure.

In an example implementation of the present disclosure, a ratio of a bottom diameter to an arch height of the spherical cap structure is not less than 3:1, and not greater than 5:1.

In an example implementation of the present disclosure, the display panel is divided into a plurality of pixel areas arranged in an array along the first direction and the second direction, one of the light-emitting units is located in one of the pixel areas; and a range of the first light-emitting device is greater than 30% of a range of the pixel area where the first light-emitting device is located.

In an example implementation of the present disclosure, a boundary of the first light-emitting device partially coincides with a boundary of the pixel area.

In an example implementation of the present disclosure, one of the first lenses overlaps with a plurality of adjacent pixel areas, and one of the lenses overlaps with only one of the light-emitting devices.

In an example implementation of the present disclosure, the display panel further includes:
an encapsulation layer, covering the light-emitting device;
wherein the lens is provided on a surface of the encapsulation layer away from the driving backplane;
a light-transmitting layer, covering the lens, wherein a refractive index of the light-transmitting layer is smaller a refractive index of the lens.

According to one aspect of the present disclosure, a manufacturing method of a display panel is provided, including:
forming a driving backplane;
forming a plurality of light-emitting devices on a side of the driving backplane;
wherein the light-emitting devices include first light-emitting devices, second light-emitting devices and third light-emitting devices emitting different colors; each of the light-emitting devices is divided into a plurality of light-emitting units distributed in an array along a first direction and a second direction; one of the light-emitting units includes the first light-emitting device and at least one of the second light-emitting device and the third light-emitting device; an area of an orthographic projection of the first light-emitting device on the driving backplane is greater than 4 times an area of an orthographic projection of any one of the second light-emitting device and the third light-emitting device on the driving backplane; and
forming a plurality of lenses arranged in an array on a side of the light-emitting devices away from the driving backplane; wherein the lenses include first lenses overlapping with the first light-emitting devices, second lenses overlapping with the second light-emitting devices, and third lenses overlapping with the third light-emitting devices; the lenses contract in a direction away from the driving backplane and are configured to converge light emitted by the light-emitting devices overlapping with the lenses; the orthographic projection of the first lens on the driving backplane is greater than orthographic projections of the second lens and the third lens on the driving backplane; a spacing between two adjacent first lenses is less than a spacing between the first lens and any one of the second lens and the third lens; and
forming the first lens through a printing process.

In an example implementation of the present disclosure, a number of light-emitting devices of one light-emitting unit is two; the light-emitting units include first light-emitting units and second light-emitting units alternately distributed in the first direction and the second direction;
light-emitting devices of the first light-emitting unit are the first light-emitting device and the second light-emitting device, and light-emitting devices of the second light-emitting unit are the first light-emitting device and the third light-emitting device;
a spacing distance between two adjacent light-emitting units is not less than 99.2 μm and less than 145.6 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and
a maximum distance between two points in a boundary of an orthographic projection of the identical third lens on the driving backplane is not greater than 25 μm;
the second lens and the third lens are formed through a photolithography process.

In an example implementation of the present disclosure, a number of light-emitting devices of one light-emitting unit is two; the light-emitting units include first light-emitting units and second light-emitting units alternately distributed in the first direction and the second direction;
light-emitting devices of the first light-emitting unit are the first light-emitting device and the second light-emitting device, and light-emitting devices of the second light-emitting unit are the first light-emitting device and the third light-emitting device;
a spacing distance between two adjacent light-emitting units is not less than 145.6 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm;
the second lens and the third lens are formed through a printing process.

In an example implementation of the present disclosure, a number of light-emitting devices of one light-emitting unit is three, including the first light-emitting device, the second light-emitting device and the third light-emitting device;
a spacing distance between two adjacent light-emitting units is not less than 145.6 μm and less than 187 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and
a maximum distance between two points in a boundary of an orthographic projection of the identical third lens on the driving backplane is not greater than 25 μm;
the second light-emitting device and the third light-emitting device are formed through a photolithography process.

In an example implementation of the present disclosure, a number of light-emitting devices of one light-emitting unit is three, including the first light-emitting device, the second light-emitting device and the third light-emitting device;
a spacing distance between two adjacent light-emitting units is not less than 187 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm;
the second lens and the third lens are formed through a printing process.

According to one aspect of the present disclosure, a display apparatus is provided, including a display panel described in any one of the above.

It should be understood that the above general description and the detailed description below are only exemplary and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and are used to explain the principles of the present disclosure together with the specification. The drawings described below are only some embodiments of the present disclosure. For ordinary technicians in this field, other drawings can be obtained based on these drawings without creative work.

FIG. 1 is a top view of an embodiment of the display panel of the present disclosure.

FIG. 2 is a cross-sectional view of an embodiment of the display panel of the present disclosure.

FIG. 3 is a cross-sectional view of an embodiment of the display panel of the present disclosure using the first arrangement.

FIG. 4 is a cross-sectional view of another embodiment of the display panel of the present disclosure using the first arrangement.

FIG. 5 is a cross-sectional view of an embodiment of the display panel of the present disclosure using the second arrangement.

FIG. 6 is a cross-sectional view of another embodiment of the display panel of the present disclosure using the second arrangement.

FIG. 7 is a schematic diagram of partial distribution of lenses of the display panel of the present disclosure.

### DETAILED DESCRIPTION

The example implementations will now be described more fully with reference to the accompanying drawings. However, the example implementations can be implemented in various forms and should not be construed as being limited to the implementations described herein; rather, these implementations are provided so that the present disclosure will be comprehensive and complete, and the concept of the example implementations will be fully conveyed to technicians in the field. The same reference numerals in the figures represent the same or similar structures, and their detailed descriptions will be omitted. Additionally, the drawings are merely schematic illustrations of the present disclosure and are not necessarily drawn to scale.

The terms “a”, “an”, “the”, “said” and “at least one” are used to indicate the existence of one or more elements/components/etc.; the terms “including” and “having” are used to indicate an open-ended inclusion and mean that there may be other elements/components/etc. in addition to the listed elements/components/etc.; the terms “first”, “second” and “third” are used only as markers, not to limit the number of the objects.

The first direction U and the second direction V in this specification are two intersecting directions. In the drawings of the present disclosure, the first direction U may be horizontal and the second direction V may be vertical, and the two are perpendicular to each other, but are not limited to this. The first direction U and the second direction V may be also not perpendicular directions. In addition, those skilled in the art can know that as the display panel rotates, the actual orientation of the first direction U and the second direction V may change, but the relative position of them two remain unchanged.

The “overlapping” of feature A and feature B in this specification means that the orthographic projection of feature A on a plane at least partially overlaps with the orthographic projection of feature B on the plane; the plane may be the surface of the driving backplane or other planes parallel to the driving backplane.

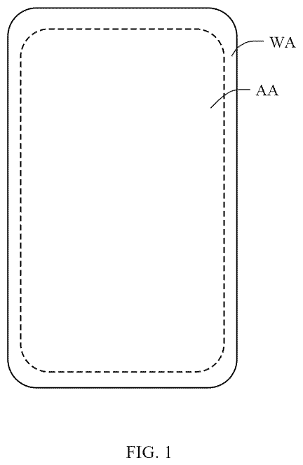

As shown in FIG. 1, the present disclosure provides a display panel, which may include a display area AA and a peripheral area WA located outside the display area AA. The peripheral area WA may be a continuous annular area surrounding the display area AA, or a discontinuous area surrounding the display area AA.

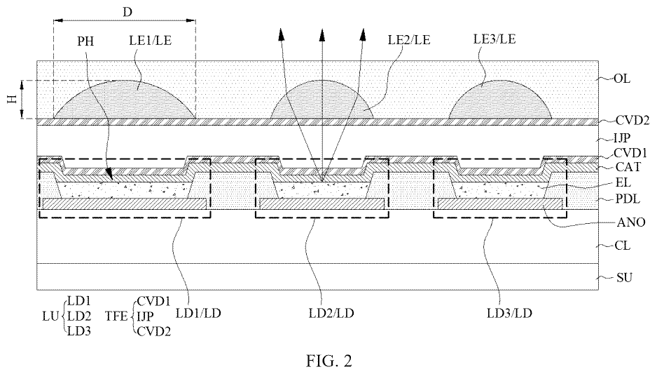

As shown in FIG. 2, the display panel may include a driving backplane BP and a plurality of light-emitting devices LD disposed on a side of the driving backplane BP.

The driving backplane BP has a driving circuit, and the driving circuit can drive the light-emitting device LD to emit light, to display an image. In some embodiments of the present disclosure, the driving backplane BP may include a substrate SU and a circuit layer CL located on a side of the substrate SU. The substrate SU may be a flat plate structure, and its material may be a hard material such as glass, or a flexible material such as polyimide. At the same time, the substrate SU may be a single-layer or multi-layer structure.

The circuit layer CL may include the above-mentioned driving circuit. For example, the driving circuit may include a pixel circuit located in the display area AA and a peripheral circuit located in the peripheral area WA, wherein the pixel circuit may be a 7T1C, 6T1C or other pixel circuits, as long as it can drive the light-emitting device LD to emit light, and its structure is not specifically limited here. The nTmC means that a pixel circuit includes n transistors (indicated by the letter “T”) and m capacitors (indicated by the letter “C”). The number of pixel circuits may be the same as the number of light-emitting devices LD, and each pixel circuit is connected to each light emitting device LD in one-to-one correspondence. The same pixel circuit may also be connected to a plurality of light-emitting devices LD, which is not specially limited herein.

The peripheral circuit is connected to the pixel circuit for inputting a driving signal to the pixel circuit, to control the light-emitting device LD to emit light. The peripheral circuit may include a gate driving circuit and a light-emitting control circuit, and may also include other circuits, and no special limitation is made here on the specific structure of the peripheral circuit.

The above-mentioned circuit layer CL may include a plurality of thin film transistors and capacitors. The thin film transistor may be a top gate or bottom gate thin film transistor, each thin film transistor may include an active layer and a gate, and the active layers of all thin film transistors are arranged in the same semiconductor layer of the same layer; or, a plurality of layers of semiconductor layers may be arranged, and the active layers of different thin film transistors may be distributed in different semiconductor layers. The material of a semiconductor layer may be polysilicon or metal oxide, which is not specifically limited here.

Taking the top gate thin film transistor as an example, the circuit layer CL may include a semiconductor layer, a first gate insulating layer, a first gate layer, a second gate insulating layer, a second gate layer, an interlayer dielectric layer, a first source/drain layer, a passivation layer, a first flat layer, a second source/drain layer, and a second flat layer, which are sequentially stacked in a direction away from the substrate SU. The specific pattern of each film layer depends on the specific composition of the driving circuit, which is not specifically limited here.

As shown in FIG. 2, the light-emitting device LD may be located in the display area AA, and it may be an OLED (organic light-emitting diode) using an organic light-emitting material. For example, the light-emitting device LD may include a first electrode ANO, a light-emitting layer EL, and a second electrode CAT sequentially stacked in a direction away from the driving backplane BP. By applying an electrical signal to the first electrode ANO and the second electrode CAT, the light-emitting layer EL may be excited to emit light, the specific light-emitting principle is not described in detail here. The first electrode ANO may be used as an anode, and the second electrode CAT may be used as a cathode, and materials of them two include conductive materials such as metals and metal oxides. The light-emitting layer EL may include a hole injection layer, a hole transport layer, a light-emitting material layer, an electron transport layer, and an electron injection layer sequentially stacked in a direction away from the driving backplane BP. Other structures may also be adopted, as long as they can cooperate with the first electrode ANO and the second electrode CAT to emit light.

As shown in FIG. 2, the display panel may also include a pixel definition layer PDL separating the light-emitting devices LD, which may be provided on the same surface of the driving backplane BP with the light-emitting device LD. For example, the pixel definition layer PDL may be provided on the surface of the second flat layer away from the substrate SU with the first electrode ANO. At the same time, the thickness of the pixel definition layer PDL is greater than the thickness of the first electrode ANO, and covers a partial area of each first electrode ANO, and has a pixel opening PH that exposes each first electrode ANO, and one pixel opening PH exposes one first electrode ANO.

As shown in FIG. 2, the light-emitting layer EL and the second electrode CAT are sequentially stacked on the first electrode ANO in the pixel opening PH. In some embodiments, the light-emitting layer EL is a continuous whole-layer structure, and the light-emitting layer EL not only covers the area of the first electrode ANO exposed by the pixel opening PH, but also covers the pixel definition layer PDL, and the second electrode CAT is a continuous whole-layer structure that covers the light-emitting layer EL. In some embodiments, the light-emitting layer EL is a discontinuous structure, and the light-emitting layer EL of each light-emitting device LD is independently spaced apart from each other, then the second electrode CAT is a continuous whole-layer structure, and the part of the second electrode CAT located in the pixel opening PH covers the light-emitting layer EL, and the part of the second electrode CAT located outside the pixel opening PH can also cover the pixel definition layer PDL.

As shown in FIG. 2, each light-emitting device LD is defined by the pixel definition layer PDL, wherein the range of the pixel opening PH is the range of the light-emitting device LD. That is, the shape and size of the orthographic projection of the pixel opening PH on the substrate SU is the shape and size of the orthographic projection of the light-emitting device LD on the substrate SU. At the same time, the shape of the pixel opening PH is the shape of its orthographic projection on the driving backplane BP and the substrate SU, etc., and the shape can be a polygon such as a rectangle, or a circle, etc. The definition of the shape and size of the light-emitting device LD in this specification is based on the shape and size of the pixel opening PH. For example, the size of the light-emitting device LD is the size of its pixel opening PH.

As shown in FIG. 2, the above-mentioned light-emitting device LD includes a first light-emitting device LD1, a second light-emitting device LD2, and a third light-emitting device LD3 emitting different colors. For example, the first light-emitting device LD1 is used to emit blue light, the second light-emitting device LD2 is used to emit red light, and the third light-emitting device LD3 is used to emit green light. The number of light-emitting devices LD of each color is plural, but the number of light-emitting devices LD of different colors is not necessarily the same.

As shown in FIG. 2, in some embodiments of the present disclosure, each light-emitting device LD can be divided into a plurality of light-emitting units LU distributed in an array along a first direction U and a second direction V, and one light-emitting unit LU may include a plurality of light-emitting devices LD, which includes a first light-emitting device LD1 and at least one of a second light-emitting device LD2 and a third light-emitting device LD3.

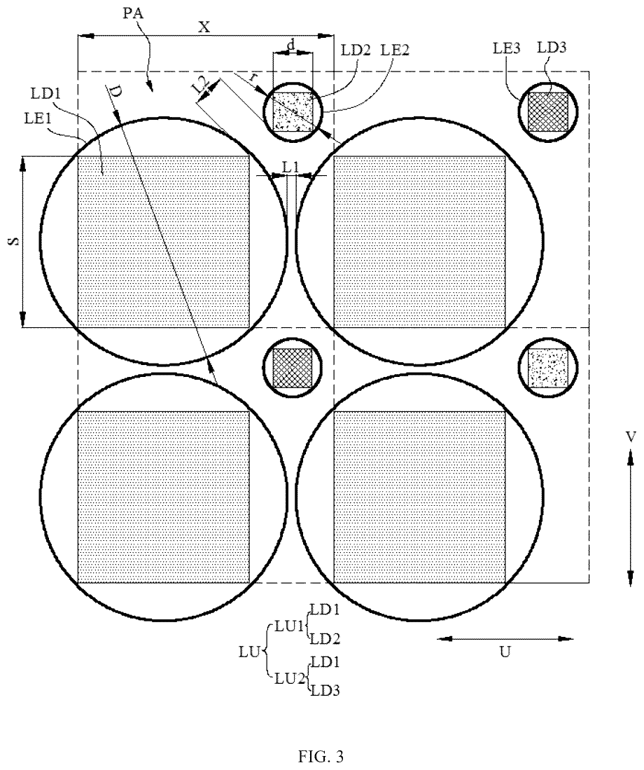

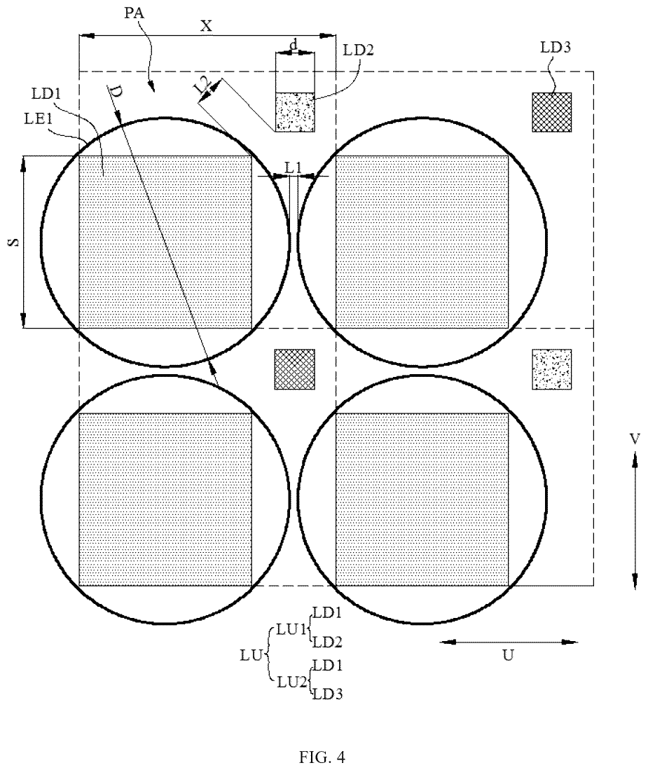

For example, as shown in FIG. 3 and FIG. 4, in the first arrangement, a light-emitting unit LU includes two light-emitting devices LD, and both include a first light-emitting device LD1; at the same time, each light-emitting unit LU can be divided into at least two categories, including a first light-emitting unit LU1 and a second light-emitting unit LU2, and the first light-emitting unit LU1 may also include a second light-emitting device LD2, and the second light-emitting unit LU2 may also include a third light-emitting device LD3. The first light-emitting unit LU1 and the second light-emitting unit LU2 are alternately distributed in the first direction U, and the first light-emitting unit LU1 and the second light-emitting unit LU2 are alternately distributed in the second direction V. In this arrangement, a sub pixel rendering (SPR) algorithm can be used to control light emission of each light-emitting device LD by borrowing color, so that adjacent light-emitting units LU can share the light-emitting device LD to achieve color display. The specific algorithm will not be described in detail here.

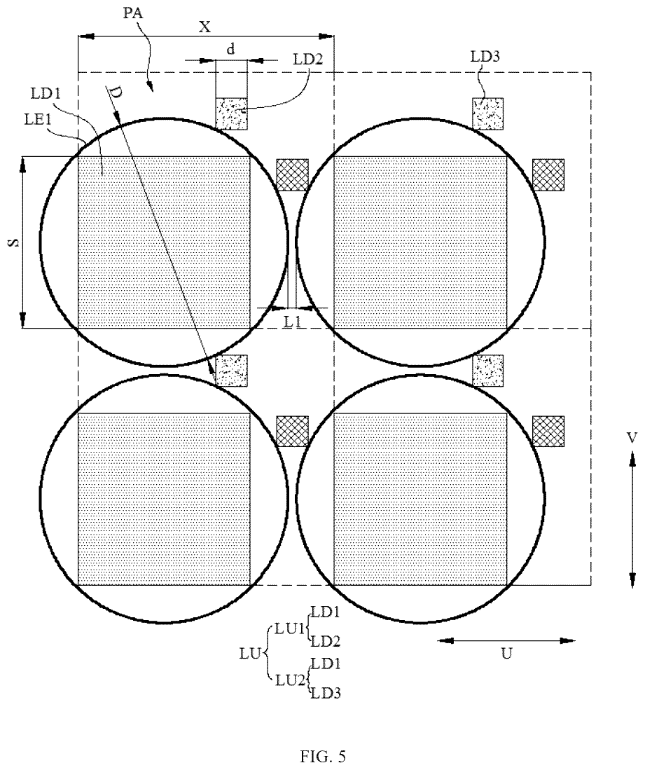

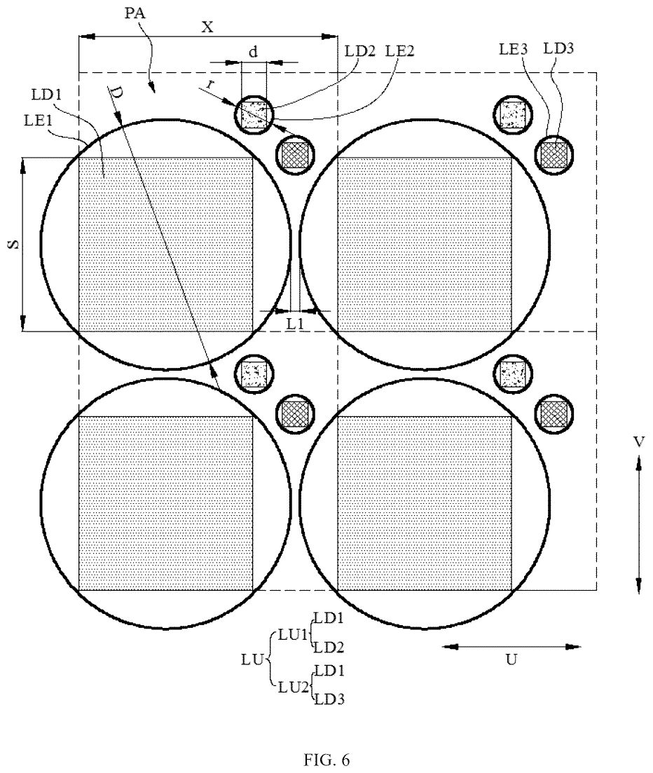

As shown in FIGS. 5 and 6, in the second arrangement, the number of light-emitting devices in a light-emitting unit LU is three, which includes a first light-emitting device LD1, a second light-emitting device LD2, and a third light-emitting device LD3. Each light-emitting unit LU is arranged in an array along the first direction U and the second direction V, and the light-emitting devices LD in different light-emitting units LU can be arranged in the same manner, or in different arrangements.

In some embodiments of the present disclosure, materials of the light-emitting layers EL of light-emitting devices LD of different colors are different, and the life of the light-emitting device LD emitting blue light is relatively low, and the difference in life with the light-emitting devices LD of other colors can be reduced by increasing the light-emitting area. For example, the area of the first light-emitting device LD1 emitting blue light can be larger than the area of the second light-emitting device LD2 emitting red light and the third light-emitting device LD3 emitting green light, that is, the orthographic projection of the pixel opening PH of the first light-emitting device LD1 on the driving backplane BP is larger than the orthographic projection of the pixel openings PH of the second light-emitting device LD2 and the third light-emitting device LD3 on the driving backplane BP. Furthermore, the area of the orthographic projection of the first light-emitting device LD1 on the driving backplane BP can be larger than 4 times the area of the orthographic projection of any of the second light-emitting device LD2 and the third light-emitting device LD3 on the driving backplane BP, thereby improving the uniformity of the life of light-emitting devices LD of different colors and ensuring the uniformity of the overall brightness of the panel.

As shown in FIG. 2, in some embodiments of the present disclosure, the display panel may further include an encapsulation layer TFE, which may cover each light-emitting device LD to block external water and oxygen, to prevent them from corroding the light-emitting device LD. For example, the encapsulation layer TFE may be encapsulated in a thin film manner, which may include a first inorganic layer CVD1, an organic layer IJP and a second inorganic layer CVD2.

The first inorganic layer CVD1 may cover each light-emitting device LD, that is, the first inorganic layer CVD1 may cover the surface of the second electrode CAT away from the driving backplane BP. The material of the first inorganic layer CVD1 may include inorganic insulating materials such as silicon nitride and silicon oxide.

The organic layer IJP may be disposed on the surface of the first inorganic layer CVD1 away from the driving backplane BP, and the boundary of the organic layer IJP may be limited to the inner side of the boundary of the first inorganic layer CVD1 by a blocking dam located in the peripheral area WA. At the same time, the boundary of the orthographic projection of the organic layer IJP on the driving backplane BP may be located in the peripheral area WA, which ensures that the organic layer IJP can cover each light-emitting device LD.

The second inorganic layer CVD2 may cover the organic layer IJP and the first inorganic layer CVD1 not covered by the organic layer IJP, and the intrusion of water and oxygen may be blocked by the second inorganic layer CVD2, and the planarization may be achieved by the organic layer IJP having fluidity before curing. The material of the second inorganic layer CVD2 may include inorganic insulating materials such as silicon nitride and silicon oxide.

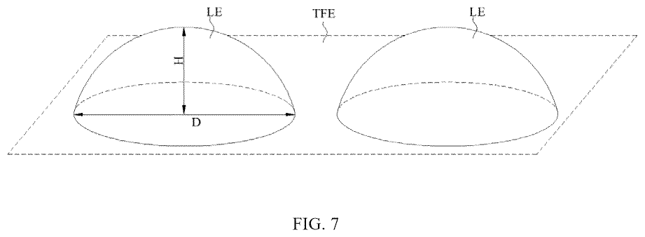

As shown in FIG. 2, in some embodiments of the present disclosure, a plurality of lenses LE formed of insulating and light-transmitting materials may be provided on the side of the light-emitting device LD away from the driving backplane BP, and the light-transmitting material may be an optical adhesive, etc., which is not specifically limited here. The lens LE overlaps with the light emitting device LD, and the lens LE can contract in the direction away from the driving backplane BP, so that the light emitted by the light emitting device LD overlapping with the lens is converged, that is, the divergence angle of the light is reduced, which can improve the light extraction efficiency of the display panel within a certain angle, thereby improving the brightness. In actual use, it can be observed that the brightness of the front of the display panel is improved. For example, as shown in FIGS. 2 and 7, the shape of the lens LE can be a spherical cap structure, which can be regarded as a part of a sphere and can play a role in converging light. The lens LE can also be a circular truncated cone, a frustum of a pyramid, etc., as long as it can converge light.

As shown in FIG. 2, in some embodiments of the present disclosure, the lens LE is provided on the surface of the encapsulation layer TFE away from the driving backplane BP. For example, the lens LE can be provided on the surface of the second inorganic layer CVD2 away from the driving backplane BP. The lens LE can also be arranged in the encapsulation layer TFE, as long as it is located on the side of the light emitting device LD away from the driving backplane BP. At the same time, the lens LE and the light emitting device LD can overlap in a one-to-one correspondence, that is, one light emitting device LD overlaps with one lens LE, so that one lens LE converges the light emitted by one light emitting device LD. The boundary of one lens LE can be larger than the boundary of the light emitting device LD overlapping with it, that is, the orthographic projection of one light emitting device LD on the driving backplane BP is located within the orthographic projection of the lens LE overlapping with it on the driving backplane BP, so that more light can enter the lens LE.

As shown in FIG. 2, in some embodiments of the present disclosure, based on the above-mentioned first light emitting device LD1, second light emitting device LD2 and third light emitting device LD3, the lens LE can be divided into a first lens LE1, a second lens LE2 and a third lens LE3. The first lens LE1 overlaps with the first light emitting device LD1, the second lens LE2 overlaps with the second light emitting device LD2, and the third lens LE3 overlaps with the third light emitting device LD3. Correspondingly, if the boundary of the first light emitting device LD1 is larger than the second light emitting device LD2 and the third light emitting device LD3, the boundary of the first lens LE1 is also larger than the second lens LE2 and the third lens LE3.

In some other embodiments of the present disclosure, as shown in FIG. 3, a first lens LE1 may be provided for the first light emitting device LD1, and a lens LE may be provided for one of the second light emitting device LD2 and the third light emitting device LD3. Alternatively, as shown in FIG. 4, neither the second light emitting device LD2 nor the third light emitting device LD3 is provided with the lens LE. That is, the display panel of the present disclosure at least has the first lens LE1, and the second lens LE2 and the third lens LE3 may be absent.

As shown in FIG. 2, in some embodiments of the present disclosure, the lens LE is provided on the surface of the encapsulation layer TFE away from the driving backplane BP, so that the surface is uneven, and each lens LE can be covered with a light-transmitting layer OL, the light-transmitting layer OL can be made of an insulating light-transmitting material, and the refractive index of the light-transmitting layer OL is less than the refractive index of the lens LE, to ensure that the lens LE can gather light. At the same time, the thickness of the light-transmitting layer OL is not less than the thickness of the lens LE, so that flattening can be achieved; thus, a touch layer or other film layers can be stacked on the side of the light-transmitting layer OL away from the driving backplane BP.

When manufacturing the lens LE, a photolithography process can be used, which can achieve patterning through a mask and a photoresist, etc. to obtain a plurality of lenses LE arranged at intervals. The specific process will not be described in detail here. However, inventors have found that there is an upper limit to the size of the lens LE that can be formed by the photolithography process. Under the condition that the structure meets the requirements, the maximum distance between two points in the boundary of the orthographic projection of the formed lens LE on the driving backplane BP is not greater than 25 μm. For example, as shown in FIGS. 2 and 7, the lens LE is a spherical cap structure, which may include a circular bottom surface and a spherical cap covering the bottom surface, and the spherical cap is a part of the spherical surface; the diameter D of the bottom surface is the maximum distance, which is generally not greater than 25 μm; the maximum distance between the spherical cap and the bottom surface is the arch height H of the spherical cap structure. Combined with the above description, in order to improve the life of some light-emitting devices, it is necessary to increase their size. For example, the first light-emitting device LD1 emits blue light, and it is larger than the second light-emitting device LD2 and the third light-emitting device LD3, and the larger the size of the display panel is, the larger the first light-emitting device LD1 is. At this time, the upper limit of the photolithography process will limit the size of the first light-emitting device LD1.

In addition, in order to ensure that the lens LE improves the light extraction efficiency of the light-emitting device LD, it is necessary to arrange the light-emitting device LD and the lens LE in a one-to-one correspondence. One light-emitting device LD overlaps with only one lens LE, in this case, as for the lens LE of the spherical cap structure and the rectangular (the shape of the orthographic projection on the driving backplane BP) pixel opening PH, in order to ensure that the size of the lens LE is not less than the light-emitting device LD, the diameter D of the bottom surface of the lens LE (taking the first lens LE1 in the figure as an example, the diameters of the bottom surfaces of the second lens LE2 and the third lens LE3 are r) needs to be not less than the length of the diagonal of the pixel opening PH, which further limits the size of the light-emitting device LD and also limits the size of the lens LE.

In some embodiments of the present disclosure, the ratio of diameter D of the bottom surface to the arch height H of the spherical cap structure can be not less than 2:1, to ensure the effect of converging light. In addition, the ratio of diameter D of the bottom surface to the arch height H can be limited to be not more than 5:1.

The following table shows the aperture (i.e. bottom diameter) D and arch height H of the lens of a spherical cap structure formed by using different droplet counts when printing with materials H0603A and H0603B at the lyophobic interface:

| | lyophobic interface | |
|---|---|---|
| | CSS | |
| | printing material | |
| droplet | H0603A | H0603B |

| count | D (μm) | H (μm) | D ((μm) | H (μm) |
|---|---|---|---|---|
| 1 | 40.07 | 11.84 | 36.83 | 7.79 |
| 2 | 48.00 | 14.92 | 46.7 | 10.21 |
| 3 | 54.03 | 17.17 | 52.17 | 11.89 |
| 4 | 58.63 | 18.95 | 56.83 | 13.41 |
| 5 | 62.80 | 20.36 | 61.93 | 14.47 |

CSS is a material of the lyophobic interface, which is a polymer. The lyophobic interface can be the surface of the encapsulation layer TFE.

Considering the above-mentioned process limitations, the inventors of the present disclosure propose that the arrangement of the light-emitting devices LD can be designed, and different processes can be used in different situations to form light-emitting devices LD and lenses LE of different sizes, thereby breaking through the above-mentioned limitations on the light-emitting device LD and lens LE. The following is a detailed description.

As shown in FIGS. 3 to 6, the light-emitting units LU can be arranged in a plurality of columns along the first direction U, and one column has a plurality of light-emitting units LU; at the same time, the light-emitting units LU can be arranged in a plurality of rows in the second direction V, and each row has a plurality of light emitting units LU. In the light emitting unit LU, the size of the first light emitting device LD1 is larger than the size of the second light emitting device LD2 and the third light emitting device LD3. For example, the first light emitting device LD1 emits blue light, the second light emitting device LD2 emits red light, and the third light emitting device LD3 emits green light. When arranging the light emitting units LU, the first light emitting device LD1 can be used as a reference, the first light emitting devices LD1 of each light emitting unit LU can be arranged in an array along the first direction U and the second direction V, and the second light emitting devices LD2 and the third light emitting devices LD3 are distributed around the first light emitting devices LD1.

In some embodiments of the present disclosure, the spacing L2 between two adjacent light-emitting devices LD is not less than 22 μm, that is, greater than or equal to 22 μm; the spacing L2 between two light-emitting devices LD is the spacing between two adjacent pixel openings PH, and the spacing L2 is the maximum value of the width of the pixel definition layer PDL between two pixel openings PH. The pixel definition layer PDL can be patterned by a photolithography process to obtain a pixel opening PH. The inventors have found that using 22 μm as the upper limit of the size when patterning the pixel definition layer PDL by a photolithography process can reduce the risk of abnormal patterns in the pixel definition layer PDL.

As shown in FIGS. 3 to 6, in order to prolong the life of the first light-emitting device LD1, its area needs to be increased. For this purpose, the lower limit of the size of the first light-emitting device LD1 can be limited. In some embodiments of the present disclosure, taking the first light-emitting device LD1 emitting blue light as an example, the boundary of its orthographic projection on the driving backplane BP is a polygon, which can be a rectangle or other shapes, and the side length S of at least one side of the polygon is greater than 18 μm; for example, the polygon is a square, and its side length S is greater than or equal to 18 μm; or, the polygon is a rectangle, and the length of its long side or short side is greater than or equal to 18 μm.

Under the above-mentioned limitation of 18 μm, the pixel opening PH is large, and it is difficult to form a first lens LE1 that can completely cover the pixel opening PH of the first light-emitting device LD1 through a photolithography process. Therefore, the first lens LE1 can be formed through a printing process, so that the first lens LE1 matching the size of the first light-emitting device LD1 can be formed.

As shown in FIGS. 3 to 6, the range of the orthographic projection of the first light-emitting device LD1 on the driving backplane BP is larger than the range of the orthographic projection of the second light-emitting device LD2 and the third light-emitting device LD3 on the driving backplane BP, so that the light-emitting range of the first light-emitting device LD1 is larger, which is beneficial to prolonging the life of the first light-emitting device LD1. Correspondingly, the orthographic projection of the first lens LE1 on the driving backplane BP is larger than the orthographic projection of the second lens LE2 and the third lens LE3 on the driving backplane BP, that is, the range of the first lens LE1 is larger than the range of the second lens LE2 and the third lens LE3. Further, the spacing L1 between two adjacent first lenses LE1 can be smaller than the spacing between the first lens LE1 and any one of the second lens LE2 and the third lens LE3, so that the first light-emitting device LD1 and the first lens LE1 are arranged more closely, which is beneficial to improving the resolution.

Further, the spacing L1 between two adjacent first lenses LE1 can be not less than 10 μm, that is, greater than or equal to 10 μm. When the first lens LE1 is formed by the printing process, the droplet formed by the material of the lens LE has a certain flying speed, when contacting the printed surface (for example, the surface of the encapsulation layer TFE away from the driving backplane BP), spreading will occur, that is, due to the existence of inertia, the spreading angle is less than the contact angle, that is, there is a tendency for the droplet to be flattened; and after the spreading angle reaches the maximum value, the droplet will contract under the action of surface tension, and the spreading angle will eventually remain stable near the contact angle, to form a lens LE. The above-mentioned limitation of 10 μm can prevent the droplets of adjacent first lenses LE1 from contacting and connecting during the spreading process, thereby ensuring that each lens LE is independent of each other.

As shown in FIGS. 3 to 6, in some embodiments of the present disclosure, the display panel can be divided into a plurality of pixel areas PA distributed in an array along the first direction U and the second direction V, and a light-emitting unit LU can be located in a pixel area PA, that is, a first light-emitting device LD1 can be set in a pixel area PA, and at least one of a second light-emitting device LD2 and a third light-emitting device LD3 can also be set in a pixel area PA. At the same time, the boundary of the first light-emitting device LD1 can be partially overlapped with the boundary of the pixel area PA, that is, the boundary of the pixel area PA can be defined by the boundary of the first light-emitting device LD1, and the boundary of the first light-emitting device LD1 is the boundary of its orthographic projection on the driving backplane BP or the substrate SU. For example, the boundary of the first light-emitting device LD1 is rectangular, and the extension lines of each side thereof intersect with the extension lines of the boundaries of the adjacent first light-emitting devices LD1, and a plurality of rectangular pixel areas PA can be divided in the display panel, and the boundary of the first light-emitting device LD1 is located on the boundary of the pixel area PA. In this way, it is conducive to fully utilizing the space in the pixel area PA and increasing the range of the first light-emitting device LD1. For example, in some embodiments, the range of the first light-emitting device LD1 can be greater than 30% of the range of the pixel area PA where it is located, and it can also be greater than 40% thereof or higher.

Further, based on the distribution of the pixel area PA and the light-emitting device LD, the orthographic projection of the first light-emitting device LD1 on the driving backplane BP is located within the orthographic projection of the first lens LE1 overlapping with it on the driving backplane BP, that is, the first lens LE1 is not smaller than the first light-emitting device LD1 overlapping with it, and a part of the boundary of the first light-emitting device LD1 can be used as a part of the boundary of the pixel area PA, so that one first lens LE1 can overlap with a plurality of adjacent pixel areas PA, but one first lens LE1 overlaps with only one light-emitting device LD.

As shown in FIG. 3, in some embodiments of the present disclosure, a display panel of the first arrangement described above is adopted. The light-emitting unit LU may include a first light-emitting unit LU1 and a second light-emitting unit LU2, the first light-emitting unit LU1 includes a first light-emitting device LD1 and a second light-emitting device LD2, without a third light-emitting device LD3; the second light-emitting unit LU2 includes a first light-emitting device LD1 and a third light-emitting device LD3, without a second light-emitting device LD2.

The spacing distance X between two adjacent light emitting units LU may be not less than 99.2 μm (i.e., greater than or equal to 99.2 μm) and less than 145.6 μm. For example, the spacing distance between two adjacent light emitting units LU is 99.2 μm, 100 μm, 120 μm, 145.6 μm, etc. The spacing distance X between two adjacent light emitting units LU is the sum of the width S of the pixel opening PH of the first light emitting device LD1 of the two adjacent light emitting units LU in the first direction U or the second direction V and the width of the pixel definition layer PDL between the two pixel openings PH.

As shown in FIG. 3, the orthographic projections of the second light emitting device LD2 and the third light emitting device LD3 on the driving backplane BP are polygon, and the side length of at least one side of the polygon is not greater than 18 μm, that is, less than or equal to 18 μm. The pixel openings PH of the second light emitting device LD2 and the third light emitting device LD3 can be formed by a photolithography process. At the same time, the maximum distance between two points in the boundary of the orthographic projection of the same second lens LE2 on the driving backplane BP is not greater than 25 μm; the maximum distance between two points in the boundary of the orthographic projection of the same third lens LE3 on the driving backplane BP is not greater than 25 μm. At this size, the second lens LE2 and the third lens LE3 can be formed by a photolithography process. As shown in FIG. 4, the second lens LE2 and the third lens LE3 may also be not provided.

As shown in FIG. 3, in some embodiments of the present disclosure, the spacing distance X between two adjacent light emitting units LU can be not less than 145.6 μm, that is, greater than or equal to 145.6 μm. The orthographic projections of the second light emitting device LD2 and the third light emitting device LD3 on the driving backplane BP are polygon, and the side length of at least one side of the polygon is greater than 18 μm. The pixel openings PH of the second light emitting device LD2 and the third light emitting device LD3 can be formed by a photolithography process. At the same time, the maximum distance between two points in the boundary of the orthographic projection of the same second lens LE2 on the driving backplane BP is greater than 25 μm; the maximum distance between two points in the boundary of the orthographic projection of the same third lens LE3 on the driving backplane BP is greater than 25 μm. At this size, the second lens LE2 and the third lens LE3 can be formed by a printing process.

As shown in FIGS. 5 and 6, as for a display panel using the second arrangement described above, each light emitting unit LU may include three light emitting devices, namely, a first light emitting device LD1, a second light emitting device LD2, and a third light emitting device LD3.

In some embodiments of the present disclosure, the spacing distance between two adjacent light emitting units LU may be not less than 145.6 μm (i.e., greater than or equal to 145.6 μm) and less than 187 μm. The orthographic projections of the second light-emitting device LD2 and the third light-emitting device LD3 on the driving backplane BP are polygon, and the side length of at least one side of the polygon is not greater than 18 μm, that is, less than or equal to 18 μm. The pixel openings PH of the first light-emitting device LD1, the second light-emitting device LD2, and the third light-emitting device LD3 can be formed by a photolithography process. At the same time, the maximum distance between two points in the boundary of the orthographic projection of the same second lens LE2 on the driving backplane BP is not greater than 25 μm, that is, less than or equal to 25 μm; the maximum distance between two points in the boundary of the orthographic projection of the same third lens LE3 on the driving backplane BP is not greater than 25 μm, that is, less than or equal to 25 μm. At this size, the second lens LE2 and the third lens LE3 can be formed by a photolithography process.

In some embodiments of the present disclosure, the spacing distance between two adjacent light-emitting units LU can be not less than 187 μm, that is, greater than or equal to 187 μm. The orthographic projections of the second light-emitting device LD2 and the third light-emitting device LD3 on the driving backplane BP can be polygon, and the side length of at least one side of the polygon is greater than 18 μm. At the same time, the maximum distance between two points in the boundary of the orthographic projection of the same second lens LE2 on the driving backplane BP is greater than 25 μm; the maximum distance between two points in the boundary of the orthographic projection of the same third lens LE3 on the driving backplane BP is greater than 25 μm. Under this size, the second lens LE2 and the third lens LE3 can be formed by a printing process.

The following describes the determination method of the above values, taking the pixel opening PH of each light-emitting device as a square and the lens LE as a spherical cap structure as an example:

As shown in FIG. 3, for a certain spacing distance X, the diameter D of the first lens LE1 is the difference between the spacing distance X and the spacing L1 between two adjacent first lenses LE1, that is, D=X−L1. If the spacing L1 is 10 μm, then D=X−10.

The spacing L2 of adjacent pixel openings PH can be restricted to be greater than 22 μm. When X is too small, the value of the side length d of the orthographic projection of the pixel openings PH of the second light-emitting device LD2 and the third light-emitting device LD3 on the driving backplane BP will be less than 5 μm, which exceeds the ability to form the light-emitting layer EL by the evaporation process and cannot be prepared.

L2 is 22 μm, and the following relationship can be obtained:
D=X−10;

$${2}^{1 {/}_{2}} X = D + 22 + {2}^{1 {/}_{2}} d + 22 ;$$

d≥5;

It can be solved that X is 99.2. Therefore, when the spacing distance X is less than 99.2 μm, the light-emitting devices cannot be arranged normally in the space, and when the spacing distance X is greater than or equal to 99.2 μm, the light-emitting devices can be arranged normally. Combined with the above restrictions on the first light-emitting device LD1 and the first lens LE1, the first lens LE1 can be prepared by a printing scheme, and the second lens LE2 and the third lens LE3 are formed by a photolithography process. The diameter r of the bottom surface of the second lens LE2 and the third lens LE3 is smaller than the diameter D of the bottom surface of the first lens LE1.

When the spacing distance X is greater than 99.2 μm, as the light-emitting device LD increases, the pixel area PA will also increase, so that three light-emitting devices LD can be set in the same pixel area PA; therefore, the following relationship is obtained:
D=X−10;

$$X = D / {2}^{1 {/}_{2}} + 22 + d + 22 ;$$

d≥5;

It can be solved that X is 145.6 μm. When the spacing distance X is less than 145.6 μm, there is not enough space in the pixel area PA to set three light-emitting devices LD, and only two light-emitting devices LD can be set, that is, one light-emitting unit LU only includes two light-emitting devices LD. When the spacing distance X is equal to or greater than 145.6 μm, three light-emitting devices LD can be set in the pixel area PA, that is, one light-emitting unit LU can include three light-emitting devices LD. Then the first lens LE1 can be prepared by a printing process, and the second lens LE2 and the third lens LE3 can be prepared by a photolithography process. In this size range, although three light-emitting devices LD can be arranged in one pixel area PA, the aperture ratio of arranging two light-emitting devices LD is greater than the aperture ratio of arranging three light-emitting devices LD. For example, in an arrangement in which one light-emitting unit LU includes three light-emitting devices LD, the aperture ratio of the pixel area PA can be 43.6%, while in an arrangement in which one light-emitting unit LU includes two light-emitting devices, the aperture ratio of the pixel area PA is 45%. The aperture ratio in this specification refers to the proportion of the total area of all pixel openings PH in a pixel area PA to the area of the pixel area PA.

When the spacing distance X is equal to or greater than 145.6 μm, two light-emitting devices LD can also be arranged in the pixel area PA, that is, the second light-emitting device LD2 and the third light-emitting device LD3 are not in the same pixel area PA. At this time, the space in the pixel area PA is large, so that the sizes of the second lens LE2 and the third lens LE3 corresponding to the second light-emitting device LD2 and the third light-emitting device LD3 are large, so the first lens LE1 can be prepared using a printing process, and the second lens LE2 and the third lens LE3 can be prepared using a printing process. For example, when the spacing distance X is 145.6 μm, as for an arrangement that one light-emitting unit LU includes two light-emitting devices, the side length of the orthographic projection of the pixel openings PH of the second light-emitting device LD2 and the third light-emitting device LD3 on the driving backplane BP can reach 18.6 μm. At this time, it is difficult to form the lens LE using a photolithography process, and the second lens LE2 and the third lens LE3 can be formed using a printing process.

As shown in FIGS. 5 and 6, as the spacing distance X continues to increase, until three light-emitting devices are arranged in one pixel area PA, that is, the above second arrangement is adopted, that is, one light-emitting unit LU includes the first light-emitting device LD1, the second light-emitting device LD2 and the third light-emitting device LD3, and the side length of the orthographic projection of the pixel openings PH of the second light-emitting device LD2 and the third light-emitting device LD3 on the driving backplane BP is made to be equal to 18 μm, then:
D=X−10;

$$X = D / {2}^{1 {/}_{2}} + 22 + d + 22 ;$$

d=18;

It can be solved that the spacing distance X is 187 μm, therefore, when the spacing distance X is less than 187 μm, the second lens LE2 and the third lens LE3 corresponding to the second light-emitting device LD2 and the third light-emitting device LD3 can be prepared using a photolithography process; while when the spacing distance X is equal to or greater than 187 μm, the size of the second lens LE2 and the third lens LE3 exceeds the upper limit of the photolithography process, and a printing process can be adopted, that is, each lens LE can adopt a printing process. When the spacing distance X is equal to or greater than 187 μm, the light-emitting unit LU can also adopt the first type of arrangement, and each lens LE can adopt a printing process. In addition, within this size range, the aperture ratio in the first type of arrangement can still be greater than that in the second type of arrangement.

When the spacing distance X continues to increase, the second light-emitting device LD2 and the third light-emitting device LD3 in the second type of arrangement also increase accordingly, and when a certain spacing distance X is reached, the aperture ratio of the second arrangement is consistent with the aperture ratio of the first arrangement. At this time, the side length d′ of the orthographic projection of the second light-emitting device LD2 and the third light-emitting device LD3 in the second arrangement on the driving backplane BP is 2^{1/2} times the side length d of the orthographic projection of the second light-emitting device LD2 and the third light-emitting device LD3 in the first arrangement on the driving backplane BP. Therefore:

$$D - 34 - D / {2}^{1 {/}_{2}} = d ;$$

$$D + 10 - ( D + 44 ) / {2}^{1 {/}_{2}} = d$$

It can be solved that D=223.3 μm, and the spacing distance X is 233.3 μm.

For example, as shown in FIG. 3, in some embodiments, when the spacing distance X is 123 μm and the first arrangement mentioned above is adopted, the shape of the orthographic projection of the first light-emitting device LD1 on the driving backplane BP is a square with a side length of 80 μm, and the shape of the orthographic projection of the second light-emitting device LD2 and the third light-emitting device LD3 on the driving backplane BP is a square with a side length of 12 μm; at this time, the aperture ratio of the pixel area PA is 43.3%. However, if the existing arrangement of light emitting devices is adopted at this size and no lens LE is provided, the aperture ratio is 40.73%.

As shown in FIG. 3, when the spacing distance X is 104.4 and the first arrangement described above is adopted, the shape of the orthographic projection of the first light emitting device LD1 on the driving backplane BP is a square with a side length S of 66.8 μm, and the shape of the orthographic projection of the second light emitting device LD2 and the third light emitting device LD3 on the driving backplane BP is a square with a side length d of 6.52 μm; at this time, the aperture ratio of the pixel area PA is 41.3%. However, if the existing arrangement of light emitting devices is adopted at this size and no lens LE is provided, the aperture ratio is 32.9%.

The present disclosure provides a method for manufacturing a display panel, which can adopt a display panel of any embodiment described above, and its specific structure is not described in detail here. The manufacturing method may include steps S110 to S130, wherein:
Step S110, forming a driving backplane;
Step S120, forming a plurality of light-emitting devices on a side of the driving backplane; wherein the light-emitting devices include first light-emitting devices, second light-emitting devices and third light-emitting devices emitting different colors; each of the light-emitting devices is divided into a plurality of light-emitting units distributed in an array along a first direction and a second direction; one of the light-emitting units includes the first light-emitting device and at least one of the second light-emitting device and the third light-emitting device; an area of an orthographic projection of the first light-emitting device on the driving backplane is greater than 4 times an area of an orthographic projection of any one of the second light-emitting device and the third light-emitting device on the driving backplane;
Step S130, forming a plurality of lenses arranged in an array on a side of the light-emitting devices away from the driving backplane; wherein the lenses include first lenses overlapping with the first light-emitting devices, second lenses overlapping with the second light-emitting devices, and third lenses overlapping with the third light-emitting devices; the lenses contract in a direction away from the driving backplane and are configured to converge light emitted by the light-emitting devices overlapping with the lenses; the orthographic projection of the first lens on the driving backplane is greater than orthographic projections of the second lens and the third lens on the driving backplane; a spacing between two adjacent first lenses is less than a spacing between the first lens and any one of the second lens and the third lens; wherein the first lens is formed through a printing process.

In some embodiments of the present disclosure, a number of light-emitting devices of one light-emitting unit is two; the light-emitting units include first light-emitting units and second light-emitting units alternately distributed in the first direction and the second direction. The light-emitting devices of the first light-emitting unit are the first light-emitting device and the second light-emitting device, and light-emitting devices of the second light-emitting unit are the first light-emitting device and the third light-emitting device;
a spacing distance between two adjacent light-emitting units is not less than 99.2 μm and less than 145.6 μm. The orthographic projections of the second light-emitting device and the third light-emitting device on the driving backplane are polygon, and a side length of at least one side of the polygon is not greater than 18 μm. A maximum distance between two points in a boundary of an orthographic projection of the identical second lens on the driving backplane is not greater than 25 μm; and a maximum distance between two points in a boundary of an orthographic projection of the identical third lens on the driving backplane is not greater than 25 μm;
the second lens and the third lens are formed through a photolithography process. The maximum distance between two points in the boundary of the orthographic projection of the same first lens on the driving backplane is not less than 25 μm.

In some embodiments of the present disclosure, a number of light-emitting devices of one light-emitting unit is two; the light-emitting units include first light-emitting units and second light-emitting units alternately distributed in the first direction and the second direction. The light-emitting devices of the first light-emitting unit are the first light-emitting device and the second light-emitting device, and light-emitting devices of the second light-emitting unit are the first light-emitting device and the third light-emitting device.

A spacing distance between two adjacent light-emitting units is not less than 145.6 μm. The orthographic projections of the second light-emitting device and the third light-emitting device on the driving backplane are polygon, and a side length of at least one side of the polygon is greater than 18 μm. A maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm.

The second lens and the third lens are formed through a printing process.

In some embodiments of the present disclosure, a number of light-emitting devices of one light-emitting unit is three, including the first light-emitting device, the second light-emitting device and the third light-emitting device.

A spacing distance between two adjacent light-emitting units is not less than 145.6 μm and less than 187 μm. The orthographic projections of the second light-emitting device and the third light-emitting device on the driving backplane are polygon, and a side length of at least one side of the polygon is not greater than 18 μm. A maximum distance between two points in a boundary of an orthographic projection of the identical second lens on the driving backplane is not greater than 25 μm; and a maximum distance between two points in a boundary of an orthographic projection of the identical third lens on the driving backplane is not greater than 25 μm;
the second light-emitting device and the third light-emitting device are formed through a photolithography process.

In some embodiments of the present disclosure, a number of light-emitting devices of one light-emitting unit is three, including the first light-emitting device, the second light-emitting device and the third light-emitting device.

A spacing distance between two adjacent light-emitting units is not less than 187 μm. The orthographic projections of the second light-emitting device and the third light-emitting device on the driving backplane are polygon, and a side length of at least one side of the polygon is greater than 18 μm. A maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm;
the second lens and the third lens are formed through a printing process.

It should be noted that although the steps of the manufacturing method in the present disclosure are described in a specific order in the accompanying drawings, this does not require or imply that these steps must be performed in this specific order, or that all the steps shown must be performed to achieve the desired result. In addition or alternatively, some steps can be omitted, a plurality of steps can be combined into one step, and/or one step can be decomposed into a plurality of steps.

The present disclosure also provides a display apparatus, which may include a display panel of any of the above embodiments. The display panel is a display panel of any of the above-mentioned embodiments, and its specific structure and beneficial effects can refer to the embodiments of the display panel above, which will not be repeated here. The display apparatus disclosed in the present disclosure can be a mobile phone, a tablet computer, a TV, or a wearable device such as a smart watch, a smart bracelet, a virtual reality device, and other electronic devices with display functions, which will not be listed one by one here.

After considering the specification and practicing the disclosure disclosed herein, it will be easy for those skilled in the art to think of other embodiments of the present disclosure. This application is intended to cover any variation, use or adaptive change of the present disclosure, which follows the general principles of the present disclosure and includes common knowledge or customary technical means in the technical field that are not disclosed in the present disclosure. The description and embodiments are to be regarded as exemplary only, and the true scope and spirit of the present disclosure are indicated by the attached claims.

1. A display panel, comprising:
a driving backplane;
a plurality of light-emitting devices, provided on a side of the driving backplane; wherein the light-emitting devices comprise first light-emitting devices, second light-emitting devices and third light-emitting devices emitting different colors; each of the light-emitting devices is divided into a plurality of light-emitting units distributed in an array along a first direction and a second direction; one of the light-emitting units comprises the first light-emitting device and at least one of the second light-emitting device or the third light-emitting device; an area of an orthographic projection of the first light-emitting device on the driving backplane is greater than 4 times an area of an orthographic projection of any one of the second light-emitting device and the third light-emitting device on the driving backplane; and
a plurality of lenses, arranged in an array on a side of the light-emitting devices away from the driving backplane; the lenses comprise first lenses overlapping with the first light-emitting devices; the lenses contract in a direction away from the driving backplane and are configured to converge light emitted by the light-emitting devices overlapping with the lenses.

2. The display panel according to claim 1, wherein a spacing between two adjacent light-emitting devices is not less than 22 μm; a boundary of the orthographic projection of the first light-emitting device on the driving backplane is a polygon, and a side length of at least one side of the polygon is greater than 18 μm; a maximum distance between two points in a boundary of an orthographic projection of the identical first lens on the driving backplane is not less than 25 μm; and a spacing between two adjacent first lenses is not less than 10 μm.

3. The display panel according to claim 2, wherein the lenses further comprise second lenses overlapping with the second light-emitting devices and third lenses overlapping with the third light-emitting devices; the orthographic projection of the first lens on the driving backplane is greater than orthographic projections of the second lens and the third lens on the driving backplane;
the spacing between two adjacent first lenses is less than a spacing between the first lens and any one of the second lens and the third lens.

4. The display panel according to claim 3, wherein a number of light-emitting devices of one light-emitting unit is two; the light-emitting units comprise first light-emitting units and second light-emitting units alternately distributed in the first direction and the second direction;
light-emitting devices of the first light-emitting unit are the first light-emitting device and the second light-emitting device, and light-emitting devices of the second light-emitting unit are the first light-emitting device and the third light-emitting device.

5. The display panel according to claim 3, wherein a number of light-emitting devices of one light-emitting unit is three, comprising the first light-emitting device, the second light-emitting device and the third light-emitting device.

6. The display panel according to claim 4, wherein a spacing distance between two adjacent light-emitting units is not less than 99.2 μm and less than 145.6 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and a maximum distance between two points in a boundary of an orthographic projection of the identical third lens on the driving backplane is not greater than 25 μm.

7. The display panel according to claim 4, wherein a spacing distance between two adjacent light-emitting units is not less than 145.6 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm.

8. The display panel according to claim 5, wherein a spacing distance between two adjacent light-emitting units is not less than 145.6 μm and less than 187 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and a maximum distance between two points in a boundary of an orthographic projection of the identical third lens on the driving backplane is not greater than 25 μm.

9. The display panel according to claim 5, wherein a spacing distance between two adjacent light-emitting units is not less than 187 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm.

10. The display panel according to claim 1, wherein the lens is a spherical cap structure.

11. The display panel according to claim 10, wherein a ratio of a bottom diameter to an arch height of the spherical cap structure is not less than 2:1.

12. The display panel according to claim 1, wherein the display panel is divided into a plurality of pixel areas arranged in an array along the first direction and the second direction, one of the light-emitting units is located in one of the pixel areas; and a range of the first light-emitting device is greater than 30% of a range of the pixel area where the first light-emitting device is located, wherein a boundary of the first light-emitting device partially coincides with a boundary of the pixel area.

13. (canceled)

14. The display panel according to claim 12, wherein one of the first lenses overlaps with a plurality of adjacent pixel areas, and one of the lenses overlaps with only one of the light-emitting devices.

15. The display panel according to claim 1, further comprising:
an encapsulation layer, covering the light-emitting device;
wherein the lens is provided on a surface of the encapsulation layer away from the driving backplane;
a light-transmitting layer, covering the lens, wherein a refractive index of the light-transmitting layer is smaller a refractive index of the lens.

16. A manufacturing method of a display panel, comprising:
forming a driving backplane;
forming a plurality of light-emitting devices on a side of the driving backplane; wherein the light-emitting devices comprise first light-emitting devices, second light-emitting devices and third light-emitting devices emitting different colors; each of the light-emitting devices is divided into a plurality of light-emitting units distributed in an array along a first direction and a second direction; one of the light-emitting units comprises the first light-emitting device and at least one of the second light-emitting device or the third light-emitting device; an area of an orthographic projection of the first light-emitting device on the driving backplane is greater than 4 times an area of an orthographic projection of any one of the second light-emitting device and the third light-emitting device on the driving backplane;
forming a plurality of lenses arranged in an array on a side of the light-emitting devices away from the driving backplane; wherein the lenses comprise first lenses overlapping with the first light-emitting devices, second lenses overlapping with the second light-emitting devices, and third lenses overlapping with the third light-emitting devices; the lenses contract in a direction away from the driving backplane and are configured to converge light emitted by the light-emitting devices overlapping with the lenses; the orthographic projection of the first lens on the driving backplane is greater than orthographic projections of the second lens and the third lens on the driving backplane; a spacing between two adjacent first lenses is less than a spacing between the first lens and any one of the second lens and the third lens; and
forming the first lens through a printing process.

17. The manufacturing method according to claim 16, wherein a number of light-emitting devices of one light-emitting unit is two; the light-emitting units comprise first light-emitting units and second light-emitting units alternately distributed in the first direction and the second direction;
light-emitting devices of the first light-emitting unit are the first light-emitting device and the second light-emitting device, and light-emitting devices of the second light-emitting unit are the first light-emitting device and the third light-emitting device;
a spacing distance between two adjacent light-emitting units is not less than 99.2 μm and less than 145.6 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and a maximum distance between two points in a boundary of an orthographic projection of the identical third lens on the driving backplane is not greater than 25 μm;
the second lens and the third lens are formed through a photolithography process.

18. The manufacturing method according to claim 16, wherein a number of light-emitting devices of one light-emitting unit is two; the light-emitting units comprise first light-emitting units and second light-emitting units alternately distributed in the first direction and the second direction;
light-emitting devices of the first light-emitting unit are the first light-emitting device and the second light-emitting device, and light-emitting devices of the second light-emitting unit are the first light-emitting device and the third light-emitting device;
a spacing distance between two adjacent light-emitting units is not less than 145.6 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm;
the second lens and the third lens are formed through a printing process.

19. The manufacturing method according to claim 16, wherein a number of light-emitting devices of one light-emitting unit is three, comprising the first light-emitting device, the second light-emitting device and the third light-emitting device;
a spacing distance between two adjacent light-emitting units is not less than 145.6 μm and less than 187 μm;
the orthographic projections of the second light-emitting device and the third light-emitting device on the driving backplane are polygon, and a side length of at least one side of the polygon is not greater than 18 μm;
a maximum distance between two points in a boundary of an orthographic projection of the identical second lens on the driving backplane is not greater than 25 μm; and a maximum distance between two points in a boundary of an orthographic projection of the identical third lens on the driving backplane is not greater than 25 μm;
the second light-emitting device and the third light-emitting device are formed through a photolithography process.

20. The manufacturing method according to claim 16, wherein a number of light-emitting devices of one light-emitting unit is three, comprising the first light-emitting device, the second light-emitting device and the third light-emitting device;
a spacing distance between two adjacent light-emitting units is not less than 187 μm;
the orthographic projections of the second light-emitting device and the third light-emitting device on the driving backplane are polygon, and a side length of at least one side of the polygon is greater than 18 μm;
a maximum distance between two points in a boundary of an orthographic projection of the identical second lens on the driving backplane is greater than 25 μm; and a maximum distance between two points in a boundary of an orthographic projection of the identical third lens on the driving backplane is greater than 25 μm;
the second lens and the third lens are formed through a printing process.

21. A display apparatus, comprising a display panel, wherein the display panel comprises:
a driving backplane;
a plurality of light-emitting devices, provided on a side of the driving backplane; wherein the light-emitting devices comprise first light-emitting devices, second light-emitting devices and third light-emitting devices emitting different colors; each of the light-emitting devices is divided into a plurality of light-emitting units distributed in an array along a first direction and a second direction; one of the light-emitting units comprises the first light-emitting device and at least one of the second light-emitting device or the third light-emitting device; an area of an orthographic projection of the first light-emitting device on the driving backplane is greater than 4 times an area of an orthographic projection of any one of the second light-emitting device and the third light-emitting device on the driving backplane; and
a plurality of lenses, arranged in an array on a side of the light-emitting devices away from the driving backplane; the lenses comprise first lenses overlapping with the first light-emitting devices; the lenses contract in a direction away from the driving backplane and are configured to converge light emitted by the light-emitting devices overlapping with the lenses.
